(19) United States
(12) Patent Application Publication
(10) Pub. No.: US 2012/0177902 A1
(43) Pub. Date: Jul. 12, 2012

(54) Multiferroics that are both ferroelectric and ferromagnetic at room temperature

(76) Inventors: Judith L. Driscoll, (US); Quanxi Jia, Los Alamos, NM (US)

(21) Appl. No.: 13/199,595

(22) Filed: Sep. 1, 2011

Related U.S. Application Data
(60) Provisional application No. 61/430,482, filed on Jan. 6, 2011.

(51) Int. Cl. B32B 9/04; C30B 25/02; C30B 23/06; C01G 49/02; B32B 7/02; C30B 23/02

(52) U.S. Cl. 428/216; 428/693.1; 428/469; 204/192.15; 117/84; 117/108; 423/594.1; 117/88

(57) ABSTRACT

Multiferroic articles including highly resistive, strongly ferromagnetic strained thin films of BiFe_{0.5}Mn_{0.5}O₃ (“BFMO”) on (001) strontium titanate and Nb-doped strontium titanate substrates were prepared. The films were tetragonal with high epitaxial quality and phase purity. The magnetic moment and coercivity values at room temperature were 90 emu/cc (H=3 kOe) and 274 Oe, respectively. The magnetic transition temperature was strongly enhanced up to approximately 600 K, which is approximately 500 K higher than for pure bulk BiMnO₃.

### RELATED APPLICATIONS

This application claims the benefit of U.S. Provisional Patent Application No. 61/430,482 entitled ‘Preparation of Epitaxial Strained Single-Phase Multiferroic (Ferroelectric and Ferromagnetic) Thin Films,” which was filed Jan. 6, 2011, which is incorporated by reference herein.

### STATEMENT REGARDING FEDERAL RIGHTS

This invention was made with government support under Contract No. DE-AC52-06NA25396 awarded by the U.S. Department of Energy. The government has certain rights in the invention.

### FIELD OF THE INVENTION

The present invention relates generally to the preparation of multiferroic articles that have both ferroelectric and ferromagnetic properties at room temperature (300 K).

### BACKGROUND OF THE INVENTION

Ferromagnetic insulators and magnetoelectrics are used in logic architectures, magnetic storage devices, and spin filters in magnetic tunnel devices and have attracted tremendous interest in the last few years [1-6]. The perovskites BiMnO₃ (“BMO”) [7-10] and BiFeO₃ (“BFO”) [11-16] have been studied extensively for their magnetoelectric properties. BMO is magnetoferroic; it is magnetoelectric and also ferroelectric to 400 K [7], but BMO has a low Curie temperature [8], far below room temperature. BMO loses its magnetism above its Curie temperature (Tc=105 K). BMO is fabricated in bulk under extreme conditions of high pressure and temperature (6 GPa and 1100 K, respectively). It is possible to stabilize BMO in thin film form, but it is hard to grow BMO in a single epitaxial orientation. Rhombohedrally distorted BFO shows a ferroelectric transition at 1103 K and an antiferromagnetic transition at 640 K [11]. In spite of its high antiferromagnetic transition temperature, the net magnetism associated with spin-canting of the antiferromagnetic structure of BFO is too weak to be very useful in device applications, and the origin of magnetic hysteresis in BFO has remained controversial [12, 13].

Chemical doping and thin film studies have been undertaken to improve the electric and magnetic properties of BFO [12-21]. Substitution of Mn into BFO, for example, resulted in polycrystalline materials of the formula BiFe₍₁₋ₓ₎MnₓO₃. These materials have structures and magnetic moments that are different from those of BFO [18-21]. For example, polycrystalline BiFe_{0.8}Mn_{0.2}O₃ (i.e. BiFe₍₁₋ₓ₎MnₓO₃ wherein x=0.2) was reported to have weak ferromagnetic correlations (0.02μ_{B}) at room temperature [18]. Others have measured the magnetic moments at a temperature of 10 K for the compounds wherein x=0.1 and x=0.5. A relatively weak enhancement of the magnetic moment was observed at 10 K for BiFe_{0.5}Mn_{0.5}O₃ (10 emu/cc) compared to BiFe_{0.9}Mn_{0.1}O₃ (5 emu/cc) [19].

Structural and magnetic properties of the double perovskite compounds Sr₂FeMnO₆, Bi₂FeMnO₆, La₂CoMnO₆, and LaNiMnO₆ have been reported [22-25]. La₂CoMnO₆ is ferromagnetic with a Curie temperature of 230 K and a magnetic moment of 5.7μ_{B}/f.u. (f.u.=formula unit). A partially disordered material was reported to have a lower Tc of 134 K and lower magnetic moment of 3.53μ_{B}/f.u. [24]. Bi₂FeMnO₆ thin films typically have a magnetization value of 5.4 emu/cc (0.03μ_{B} per B-site ion) at 5 K and 9 kOe. The low magnetization value has been ascribed to the disordered nature of the material [23]. Typically, the resistivity of double perovskite compounds shows semiconducting behavior with conductively values in a range from 10 to about 102 Ωcm at room temperature [25].

There is a need for multiferroic materials that are both ferromagnetic and ferroelectric at or near room temperature. Such materials will open up a whole new range of devices, in particular in the area of magnetoelectric random access memory. Magnetoelectric random access memory would have an advantage of a much larger writing energy compared to conventional magnetic random access memory A write scheme based on the application of a voltage (such as in magnetoelectric random access memory) rather than large currents would drastically reduce the writing energy. The anti-ferromagnetic ferroelectric materials BiFeO₃ or BiMnO₃ do not provide desired magnetoelectric random access memory properties that ferroelectric ferromagnets could.

### SUMMARY OF THE INVENTION

In accordance with the purposes of the present invention, as embodied and broadly described herein, the present invention includes a magnetoferroic article comprising a strained, single phase, epitaxial thin film portion comprising a composition of the formula BiFe_{0.5}Mn_{0.5}O₃, and a substrate portion for supporting said thin film portion and for providing strain to said thin film sufficient to provide the article with both ferromagnetic and ferroelectric properties at and above room temperature (300 K)

The invention also includes a process for preparing a multiferroic article comprising a strained, single phase epitaxial film of a perovskite of the composition BiFe_{0.5}Mn_{0.5}O₃ on a substrate. The process includes forming a mixture of stoichiometric amounts of Bi₂O₃, Fe₂O₃, and MnO₂ and then sintering the mixture to form a target for deposition onto a substrate. After forming the target, it is used under suitable conditions to deposit a strained, single phase epitaxial film of a perovskite of the composition BiFe_{0.5}Mn_{0.5}O₃ on a substrate.

The invention also a strained magnetic multilayered article. The article includes a substrate for supporting an alternating multilayered structure; and a multilayered structure supported by the substrate and comprising alternating layers of BiMnO₃ layers and BiFeO₃, each of said layers comprising a thickness of from 0.38 nm to 1.52 nm.

### BRIEF DESCRIPTION OF THE DRAWINGS

The accompanying drawings, which are incorporated in and form a part of the specification, illustrate the embodiments of the present invention and, together with the description, serve to explain the principles of the invention. The patent or application file contains at least one drawing executed in color. Copies of this patent or patent application publication with color drawing(s) will be provided by the Office upon request and payment of the necessary fee. In the drawings:

FIG. 1a shows X-ray diffraction spectra (θ-2θ scan) of a pure, 33-nm thick BiFe_{0.5}Mn_{0.5}O₃ (“BFMO”) film grown on a strontium titanate (SrTiO₃, “STO”) substrate.

The inset shows finite-thickness oscillation in the vicinity of the (001) reflection. FIG. 1b shows a φ-scan of the (110) reflection of the film (top panel) and the (110) STO substrate (bottom panel). FIG. 1c shows a reciprocal space map (“RSM”) close to the (103) reflections of BFMO and (103) reflection of STO.

FIG. 2a shows a half-angle annular dark field (“HAADF”) image of the interface between BFMO and SrTiO₃. The uniform contrast indicates a homogeneous film composition to 5 nm lateral resolution with no nano-scale parasitic phases present. FIG. 2b shows a high resolution transmission electron microscope (“HRTEM”) image of the interface between BFMO and SrTiO₃. Insets show sharp Fourier transformation points indicating tetragonal symmetry (upper) and the lattice parameters of 3.93 Å in-plane and 4.03 Å out-of-plane (lower).

FIG. 3 shows magnetic hysteresis (M-H) curves in the range of −3000≦H≦3000 Oe at room temperature with the field applied in-plane (solid square) and out-of-plane (open square) for a pure BiFe_{0.5}Mn_{0.5}O₃ film grown on STO. The inset at bottom right shows temperature dependence of coercive field, while the inset at top left shows a normalized in-plane M-T curve from 300-720 K at a field of 500 Oe for a pure BFMO film. The solid line is a fit using the spin ½ Brillouin function.

FIG. 4 shows the polarization force micrograph images at room temperature for a 35-nm thick film grown on a Nb-doped SrTiO₃ substrate showing poling and ferroelectricity.

FIG. 5 shows the polarization response (phase amplitude and phase angle) as a function of tip bias for a 35-nm thick film grown on a Nb-doped SrTiO₃ substrate showing poling, ferroelectricity and hysteresis. There was no voltage degradation of the surface by the poling using an AFM tip.

FIG. 6 shows x-ray reciprocal space maps for the 1, 2, 4, and 8 unit cell samples.

FIG. 7 shows remnant magnetization (Mr) versus temperature (top) and saturation magnetization (Ms) versus temperature (bottom) for the multilayered films for 1, 2, and 4 unit cells.

FIG. 8 shows x-ray diffraction data for the 1, 2, and 4 unit cell samples. An impurity phase of Bi₂O₃ appears for the 4 unit cell sample.

### DETAILED DESCRIPTION

This invention is related to the preparation of articles with multiferroic properties at, or near, room temperature (300 K). These articles include a highly resistive, single phase, strained perovskite epitaxial film of BiFe_{0.5}Mn_{0.5}O₃ on a suitable substrate. Embodiments were prepared by depositing films of BiFe_{0.5}Mn_{0.5}O₃ by pulsed laser deposition onto (001) strontium titanate (SrTiO₃, “STO”) substrates. The substrates provide the film with a sufficient amount of strain, which leads to the article having both ferromagnetic and ferroelectric properties at room temperature. It should be understood that substrates besides STO are expected to provide articles that are also multiferroic at or near room temperature that also include a strained epitaxial film of BiFe_{0.5}Mn_{0.5}O₃ on the substrate. Other possible substrates which the films could be grown on to provide the film with sufficient strain to result in both ferromagnetic and ferroelectric properties at or near room temperature include other oxides such as, but not limited to, LaAlO₃, MgO, NdGaO₃, MgAl₂O₄, ZrO₂, YSZ, (La,Sr)(Al,Ta)O₃, other perovskite oxides besides SrTiO₃, or perovskite oxide buffered substrates such as silicon (Si).

A target for the deposition of BiFe_{0.5}Mn_{0.5}O₃ on the STO substrate was prepared by thoroughly mixing stoichiometric amounts of high purity (at least 99.99% pure) Bi₂O₃, Fe₂O₃, and MnO₂ and then sintering the mixture at 400° C. for 2 hours, and then at 800° C. for 5 hours. The sintered product was then cooled to room temperature at a rate of 10° C./min.

Embodiment articles having a strained epitaxial film of BiFe_{0.5}Mn_{0.5}O₃ on a STO substrate were prepared. They have a magnetic transition temperature of approximately 600 K and a moment of 90 emu/cc at room temperature.

Articles comprised of films of BiFe_{0.5}Mn_{0.5}O₃ on STO were prepared with deposition temperatures in a range from 600° C. to 850° C., a pulse rate from 1 Hz to 10 Hz, and duration of deposition from 3 minutes to 60 minutes. The oxygen pressure may be from 10 millitorr (mTorr) to 350 millitorr. Embodiment articles were prepared using an oxygen pressure of approximately 200 mTorr. Slight deviations from these ranges when depositing the film on the substrate resulted in a perovskite phase as well as additional minor, unwanted amounts of second phases of Fe₃O₄ or MnFe₂O₄. Films including these second phases gave very weak magnetic signals (less than 0.06μ_{B}/u.c.). Because formation of a secondary phase with a Mn:Fe ratio of 1:2 would displace the remaining film composition away from the Mn:Fe ratio of 1:1, this result indicates a) that obtaining the precise 1:0.5:0.5 Bi:Mn:Fe stoichiometry in the film is related to obtaining a strong magnetic response for the article, perhaps indicating that a maximum amount of Mn—O—Fe bonds is desirable in the BiFe_{0.5}Mn_{0.5}O₃ film, and b) secondary phases in the system are likely not responsible for the large magnetization values observed.

Articles of films of BiFe_{0.5}Mn_{0.5}O₃ on substrates have been prepared by others, but none of these articles have a large magnetization, and none are multiferroic at or near room temperature. Results reported for past studies by others indicate that films of BiFe_{0.5}Mn_{0.5}O₃ thicker than 35 nanometers (nm) have not shown strong ferromagnetism. Values of 10-20 emu/cc (0.06-0.12μ_{B}/B-site ion) were reported for 70-160 nm thick BiFe_{0.5}Mn_{0.5}O₃ films [19]. A value of 0.8 emu/cc 220-nm thick Bi₂FeMnO₆ films were also reported [23]. One possible explanation why the films of these 2 previous studies [19, 23] are not multiferroic at room temperature is that they do not have strained structures but instead, they have relaxed structures.

It may be possible to prepare articles having thicker (50 nm to 1000 nm) films of BiFe_{0.5}Mn_{0.5}O₃ on STO substrates with strong ferromagnetism, and possibly also strong ferroelectricity, if the films were to be grown very slowly (0.01-0.1 nm/min) at temperatures higher than 820° C.

Another aspect to the present invention relates to articles comprising multilayered films. For such multilayered films, interlayers in between layers of BiFe_{0.5}Mn_{0.5}O₃ (“BFMO”) are provided in order to keep the BFMO layers strained. An embodiment includes alternating layers of BFMO of 5-30 nm thickness would be interlayered with STO, or with CeO₂, or with a suitable single crystal oxide. Examples of suitable oxides for the interlayers include MgO, SrTiO₃, LaAlO₃, LSAT, and NdGaO₃. The interlayers would also be of approximately 10-30 nm in thickness. Multilayered structures with a total number of layers of from 6 to 20 or more layers may be prepared.

Another aspect of this invention that is also related to multilayered articles would not necessarily include a layer of BiFe_{0.5}Mn_{0.5}O₃. For example, an embodiment multilayered article would include alternating layers of BiMnO₃ (“BMO”) and BiFeO₃ (“BFO”), where the thickness of each BMO and BFO layer would be between 1 and 3 unit cells, (i.e. approximately 0.38 nm to approximately 1.14 nm). This multilayered structure of alternating layers of BFO and BMO would be similar to an ordered BFMO structure, wherein Fe and Mo alternate within the perovskite lattice. This multilayered embodiment may be prepared by depositing alternate layers of BMO and BFO on each other.

The Examples below provide several non-limiting embodiment articles of this invention

### Example 1

An article with a 17-nanometer (17-nm) thick strained, single phase epitaxial BiFe_{0.5}Mn_{0.5}O₃ film on single crystal SrTiO₃ substrate was prepared as follows. A single crystal (100) oriented SrTiO₃ (“STO”) was used as the substrate. The BiFe_{0.5}Mn_{0.5}O₃ film was deposited on STO by pulsed laser deposition using a KrF excimer laser (λ=248 nm). A substrate temperature of 820° C. and oxygen pressure of 100 mTorr were used during the deposition. The pulse rate was 10 Hz. A total deposition time of 83 minutes resulted in a 17-nm thick BiFe_{0.5}Mn_{0.5}O₃ film. After the deposition, the resulting article was cooled in an oxygen atmosphere of 200 Torn The BiFe_{0.5}Mn_{0.5}O₃ film shows single phase and epitaxy as proved by x-ray diffraction. The article showed ferromagnetic properties at room temperature as confirmed by magnetic hysteresis. It is expected that the article is also ferroelectric (since the substrate is the same structure and lattice parameters as the Nb doped STO substrate samples which were ferroelectric), but this was not measured yet as the substrate was not conducting and so measurements are more complicated.

### Example 2

An article with a 35-nm thick strained, single phase epitaxial BiFe_{0.5}Mn_{0.5}O₃ film on single crystal SrTiO₃ substrate was prepared as follows. A single crystal (100) oriented SrTiO₃ (STO) was used as the substrate. The BiFe_{0.5}Mn_{0.5}O₃ film was deposited on STO by pulsed laser deposition using a KrF excimer laser (λ=248 nm). A substrate temperature of 820° C. and oxygen pressure of 100 mTorr were used during the deposition. The pulse rate was 10 Hz. A total deposition time of 166 minutes resulted in a 35-nm thick BiFe_{0.5}Mn_{0.5}O₃ film. After the deposition, the resulting article was cooled in an oxygen atmosphere of 200 Torr. The BiFe_{0.5}Mn_{0.5}O₃ film shows single phase and epitaxy as proved by x-ray diffraction. The article shows ferromagnetic properties at room temperature as confirmed by magnetic hysteresis behavior. It is expected that the article is also ferroelectric (since the substrate is the same structure and lattice parameters as the Nb doped STO substrate samples which were ferroelectric), but this was not measured yet as the substrate was not conducting and so measurements are more complicated.

### Example 3

An article with a 35-nm thick strained, single phase epitaxial BiFe_{0.5}Mn_{0.5}O₃ film on single crystal Nb-doped SrTiO₃ substrate was prepared as follows. A single crystal (100) oriented Nb-doped SrTiO₃ (Nb:STO) was used as the substrate. The BiFe_{0.5}Mn_{0.5}O₃ film was deposited on Nb:STO by pulsed laser deposition using a KrF excimer laser (λ=248 nm). A substrate temperature of 820° C. and oxygen pressure of 100 mTorr were used during the deposition. The pulse rate was 10 Hz. A total deposition time of 166 minutes resulted in a 35-nm thick BiFe_{0.5}Mn_{0.5}O₃ film. After the deposition, the resulting article was cooled in an oxygen atmosphere of 200 Torr. The BiFe_{0.5}Mn_{0.5}O₃ film showed single phase and epitaxy as proved by x-ray diffraction. The article showed ferromagnetic properties at room temperature as confirmed by magnetic hysteresis behavior.

### Example 4

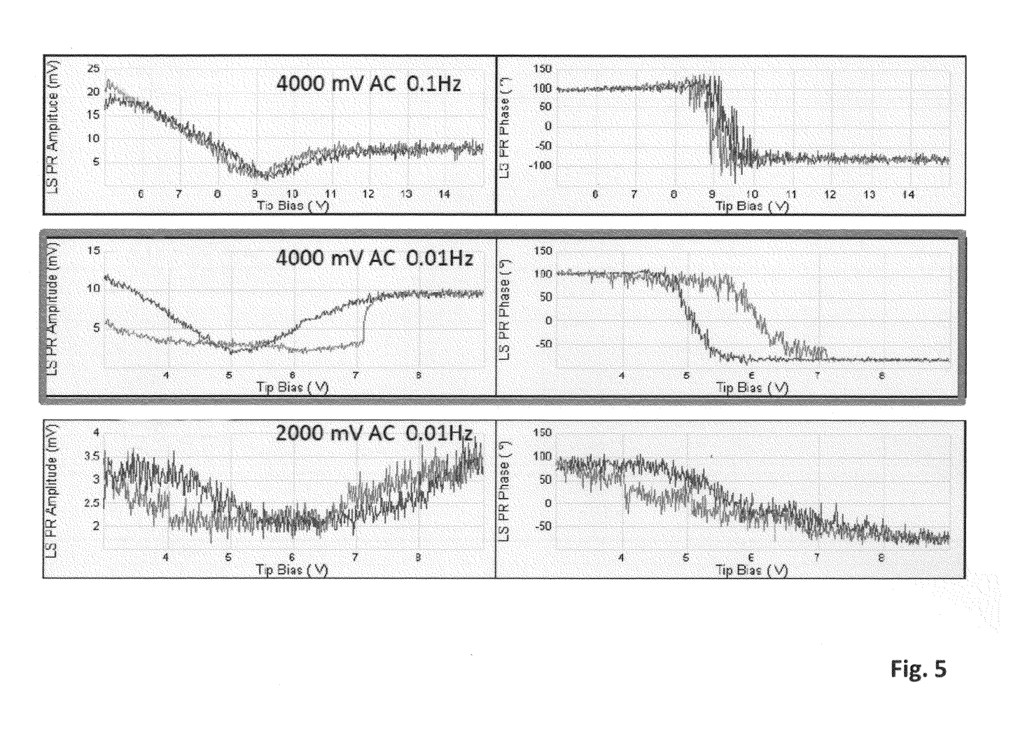

An article with a 35-nm thick strained, single phase epitaxial BiFe_{0.5}Mn_{0.5}O₃ film on single crystal Nb-doped SrTiO₃ substrate was prepared as follows. A single crystal (100) oriented Nb-doped SrTiO₃ (Nb:STO) was used as the substrate. The BiFe_{0.5}Mn_{0.5}O₃ film was deposited on Nb:STO by pulsed laser deposition using a KrF excimer laser (λ=248 nm). A substrate temperature of 820° C. and oxygen pressure of 100 mTorr were used during the deposition. The pulse rate was 10 Hz. A total deposition time of 333 minutes resulted in a 35-nm thick BiFe_{0.5}Mn_{0.5}O₃ film. After the deposition, the resulting article was cooled in an oxygen atmosphere of 200 Torr. The BiFe_{0.5}Mn_{0.5}O₃ film portion of the article showed single phase and epitaxy as proved by x-ray diffraction. The article showed both ferroelectric and ferromagnetic properties. Hence, it is likely to be multiferroic, i.e. that the ferroelectricity and ferromagnetism come from the same phase and not an impurity (since no impurity was observed in the samples). The ferroelectric properties are shown in FIG. 5

### Example 5

An article with a 11-nm thick strained, single phase epitaxial multilayered film comprised of alternating layers of BiFeO₃ and BiMnO₃ where each individual layer is 1 unit cell thick on single crystal SrTiO₃ substrate was prepared as follows. A single crystal (100) oriented SrTiO₃ substrate was used. Deposition from alternating targets of BiFeO₃ and BiMnO₃ took place by pulsed laser deposition using a KrF excimer laser (λ=248 nm). The total number of layers was 64. A substrate temperature of 820° C. and oxygen pressure of 100 mTorr were used during the deposition. The pulse rate was 10 Hz. After the deposition, the films were cooled in an oxygen atmosphere of 200 Torr. The multilayer film shows both single phase BiFeO₃ and BiMnO₃ and epitaxy as proved by x-ray diffraction. The article showed strong magnetic properties at room temperature as confirmed by the magnetic measurements.

### Example 6

An article with a 17-nm thick strained, single phase epitaxial multilayered film comprised of alternating layers of BiFeO₃ and BiMnO₃ where each individual layer is 2 unit cell thick on single crystal SrTiO₃ substrate was prepared as follows. The total number of layers was 32. A single crystal (100) oriented SrTiO₃ substrate was used. Deposition from alternating targets of BiFeO₃ and BiMnO₃ took place by pulsed laser deposition using a KrF excimer laser (λ=248 nm). A substrate temperature of 820° C. and oxygen pressure of 100 mTorr were used during the deposition. The pulse rate was 10 Hz. After the deposition, the films were cooled in an oxygen atmosphere of 200 Torr. The multilayer film shows both single phase BiFeO₃ and BiMnO₃ and epitaxy as proved by x-ray diffraction. The article shows strong magnetic properties at room temperature as confirmed by the magnetic measurements. Neither the 2 unit cell (this example) or 1 unit cell layered films (example 5 above) have yet been grown on a conducting substrate (normally (001) Nb-doped STO) so as to allow us to measure their ferroelectric properties. However, it is anticipated that the films will be ferroelectric just as for the single phase BiFe_{0.5}Mn_{0.5}O₃ films since they have the same overall composition.

### Example 7

A 25-nm thick strained, single phase epitaxial multilayered film comprised of alternating layers of BiFeO₃ and BiMnO₃ where each individual layer is 4 unit cell thick on single crystal SrTiO₃ substrate was prepared as follows. The total number of layers was 16. A single crystal (100) oriented SrTiO₃ substrate was used. Deposition from alternating targets of BiFeO₃ and BiMnO₃ took place by pulsed laser deposition using a KrF excimer laser (λ:=248 nm). A substrate temperature of 820° C. and oxygen pressure of 100 mTorr were used during the deposition. The pulse rate was 10 Hz. After the deposition, the films were cooled in an oxygen atmosphere of 200 Torr. The multilayer film shows single phase BiFeO₃ and BiMnO₃ and epitaxy as proved by x-ray diffraction. The film shows weak magnetic properties at room temperature as confirmed by the magnetic measurements, the reason being that the strain was partially relaxed in the layers for these thicker layers and also impurity phases started to form.

To confirm the phase and the crystalline quality of the thin films, high resolution X-Ray diffraction was carried out using a PHILLIPS X′PERT GEN6 diffractometer with a 4-bounce Ge monochromator. Reciprocal space maps (“RSMs”) were used to investigate the strain between the BFMO films and STO substrates. Detailed atomic structure was probed by high resolution transmission electron microscopy (“HRTEM”) using a JEOL 2010 microscope operating at 200 kV and a JEOL 4000 EX microscope operating at 400 kV. High-angle annular dark field (“HAADF”) studies were undertaken to investigate variations of film composition across the film, and energy dispersive X-ray spectroscopy (“EDX”) line profiles in the HRTEM were used to measure cation ratios. Magnetization measurements (M-T and M-H) were made using a Princeton vibrating sample magnetometer and a SQUID magnetometer (Quantum Design, MPMS). The samples were glued to the heater using silver paste. To exclude the possibility of any magnetic moment arising from the silver paste or from the substrate, the magnetizations of two substrates which had previously been heated up to the growth temperature of BFMO were measured. One was with silver paste on the backside and the other was with the silver paste removed using an ammonia and hydrogen peroxide etch. The two substrates showed clear diamagnetic hysteresis confirming that neither the substrate nor Ag paste contributed to the ferromagnetic signal from the BFMO films. The resistivity at room temperature was measured using the van der Pauw technique.

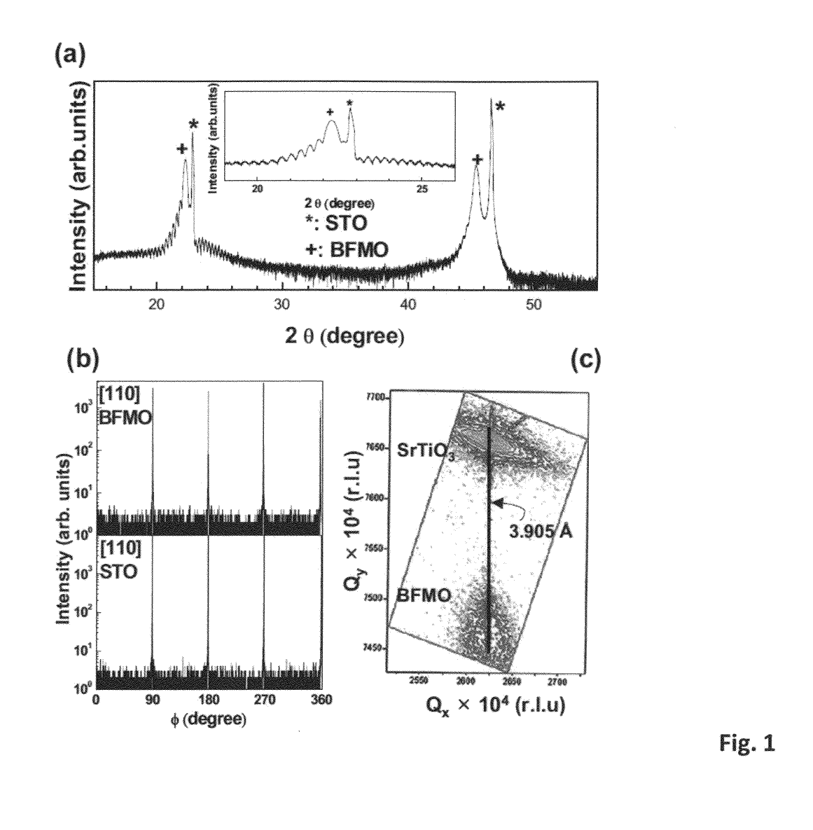

FIGS. 1a and b show the x-ray diffraction for a BiFe_{0.5}Mn_{0.5}O₃ thin film having a thickness of 33 nanometers (“nm”). The film was grown on single crystal (100) oriented SrTiO₃ (“STO”) using a KrF excimer laser (λ=248 nm). A substrate temperature of 820° C. and oxygen pressure of 100 mTorr were used during the deposition. The pulse rate was 10 Hz. A total deposition time of 166 min resulted in a 17-nm thick BiFe_{0.5}Mn_{0.5}O₃ film. After the deposition, the films were cooled in an oxygen atmosphere of 200 Torr. Other possible growth methods for the BFMO films include other physical vapour deposition methods (e.g. sputtering) as well as chemical vapour deposition (such as MOCVD) and chemical solution deposition, such as polymer-assisted deposition and sol-gel.

FIGS. 1a and 1b show θ-2θ XRD patterns and a O-scan of the (110) reflection of the film. The patterns show that the BFMO has a high phase-purity. The inset of FIG. 1a shows finite thickness oscillation in the vicinity of the (001) reflection. The very high crystallinity and a cube-on-cube, BFMO[100]∥STO[100] and BFMO[001]∥STO[001], orientation were observed. The root mean squared (“RMS”) roughness of films confirmed by atomic force microscopy (“AFM”) was around 1.8 nm, indicative of a two-dimensional growth mode. The full width at half maximum (“FWHM”) of the co-rocking curves of the (002) diffraction peaks are 0.02° which is same as the STO substrate and indicates excellent epitaxy. From the vertical lines joining the (103) BFMO and STO peaks in the RMS (FIG. 1c) the in-plane lattice parameters of the STO substrate and the BFMO film were found to be identical at 3.905 Å indicating full epitaxial strain.

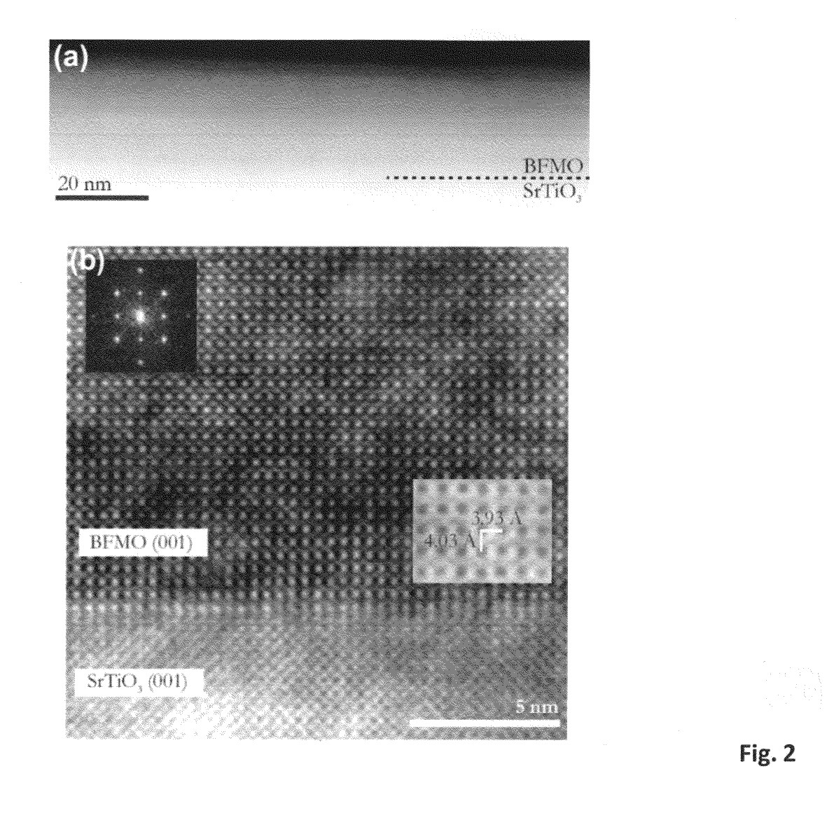

The HAADF images that are displayed in FIG. 2a showed uniform contrast throughout the film, indicating compositional homogeneity on a 5-nm scale and no nano-scale parasitic phases. This is consistent with EDX, which showed a Bi:Mn:Fe ratio of 2:1:1 also on a 10-nm scale in the different regions of the film. Perfect crystallographic registry and a cube-on-cube orientation relationship with the SrTiO₃ substrate may be seen in the TEM image of FIG. 2b. The sharp Fourier transform image shows the tetragonal symmetry (upper inset). The lattice parameters measured directly from the image (lower inset) were a=3.93±0.02 Å and c=4.03±0.02 Å (c/a≈1.03), consistent with the x-ray diffraction data.

The structure of BiFe₍₁₋ₓ₎MnₓO₃ for x near 0.5 in the bulk phase has been reported [18]. For 0.2≦x≦0.6, the structure was reported to be an orthorhombic phase with √2ap×4ap×√2ap (ap is the parameter of the cubic perovskite subcell). Another report indicates the solubility of Mn in BiFe₍₁₋ₓ₎MnₓO_{(3+δ)} at ambient pressure in the bulk to be only x=0.3. To achieve x>0.3, it was necessary to use high-pressure synthesis [21]. The tetragonal structure and the high Mn solubility in our films are different from the reports of the bulk material, which suggests a strong role of epitaxial strain in fixing the structure. Resistivity measurements on BFMO at room temperature gave a value of approximately 10⁵Ωcm which is similar to pure ferroelectric bulk BiFeO₃. This value is much larger than resistivity of 2×10⁴Ωcm for BiMnO₃ bulk and 1.8×10²Ωcm for BiMnO₃ epitaxial films [26].

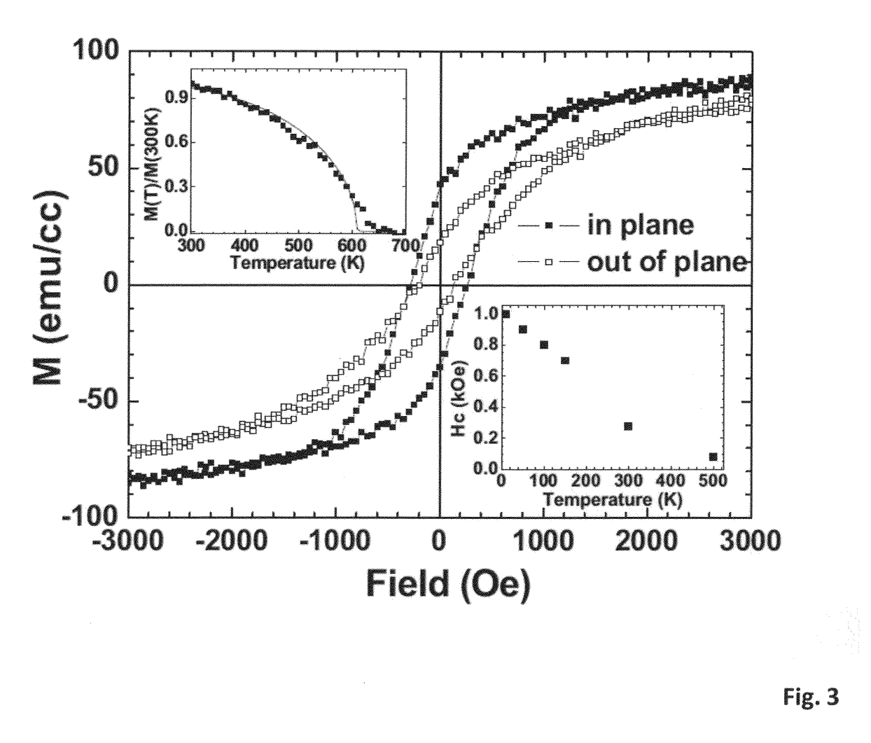

FIG. 3 shows magnetic hysteresis (M-H) curves obtained at room temperature for the article of a pure BiFe_{0.5}Mn_{0.5}O₃ film grown on an STO substrate at room temperature described in EXAMPLE 2. The inset (bottom right) shows the temperature dependence of coercivity (“Hc”). Hc decreases monotonically with increasing temperature. The shape of Hc(T) curve shows the usual behavior for a bulk ferromagnet [27]. At 300 K the magnetic moment was 90 emu/cc at 3 kOe and the coercivity was 263 Oe in plane. The saturation magnetic moment extrapolated to zero field from value at 5 T, Ms(0), was 85 emu/cc (approximately 0.55μ_{B} per unit cell) at 300 K. The Ms(0) was 115 emu/cc (approximately 0.74μ_{B} per unit cell) at 5 K. The shape of the M-H curves indicates that the easy axis lies in the film plane and that the hard axis out-of-plane. The measured moments are much higher than the 10-20 emu/cc value measured previously for 70-160 nm BiFe_{0.5}Mn_{0.5}O₃ thin films [19] or the 0.8 emu/cc value for 220 nm Bi₂FeMnO₆ thin films [23]. The temperature dependence of the magnetization is shown in FIG. 3 (top left inset); a sharp Tc above 600 K appears, which is approximately 500 K higher than for pure bulk BMO (Tc=105 K). The data can be fitted reasonably using spin ½ Brillouin function implying strong ferromagnetism.

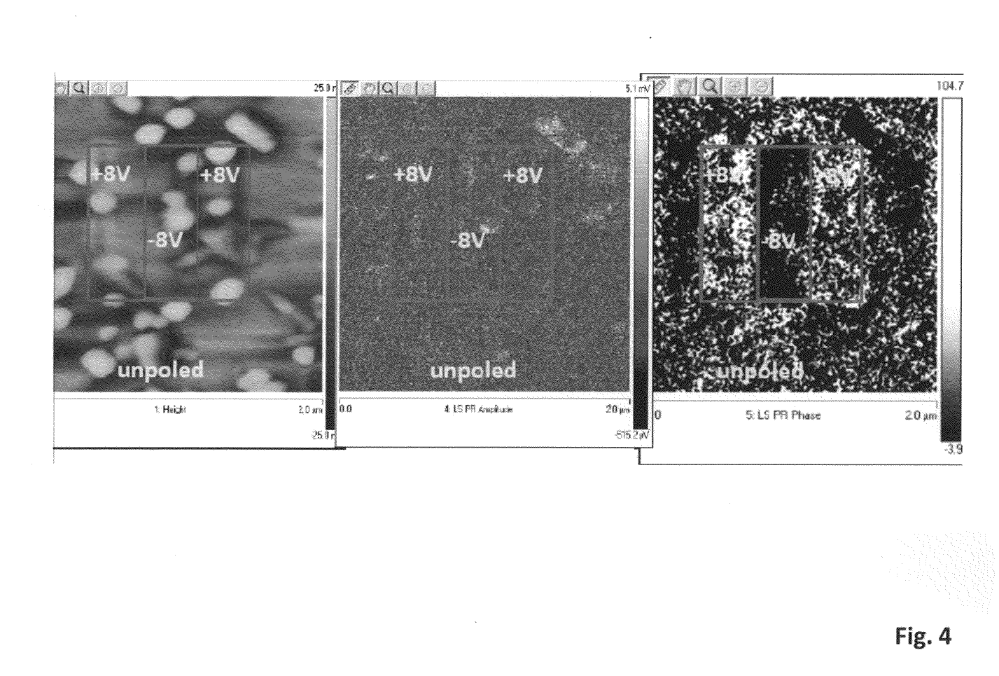

FIG. 4 shows Polarization Force Micrograph images at room temperature for the 35-nm thick film grown on a Nb-doped SrTiO₃ substrate described in Example 3. FIG. 4 shows poling and ferroelectricity. In the unpoled state, no contrast in the different regions of the film is observed. In the poled state (far right hand image) the −8 V poling shows a dark contrast compared to the bright contrast of the +8V poled regions. Hence, the sign of the polarization is switched when the sign of the voltage is switched, indicating ferroelectricity. Hence, this article is multiferroic at room temperature. FIG. 5 shows the polarization response (phase amplitude and phase angle) as a function of tip bias at room temperature in 3 different regions of the article of Example 3, which shows poling, ferroelectricity and hysteresis. In each graph there are two different lines, one being for increasing the tip bias (i.e. going to the right) and the other being for decreasing the tip bias (i.e. going to the left). The hysteresis in the phase amplitude and phase angle proves that the sample is ferroelectric. Also, there was no voltage degradation of the surface by the poling using an AFM tip.

Articles that included films of having minor amounts of additional secondary phases such as MnFe₂O₄ showed much weaker signals (less than 10 emu/cc), compared to articles with pure BiFe_{0.5}Mn_{0.5}O₃ films. The results suggest that the strongly magnetic tetragonal phase is formed only in strained, thin (approximately 35-nm and thinner), single-phase films of BFMO. For films of BFMO thicker than 35 nanometers, a magnetic signal was also obtained at room temperature but for films of BFMO approximately 50 nm and above that were grown on STO, the signals were as low as 10 emu/cc.

In a recent theoretical study, Pálová et al. compared the relative energies of various (BFO)_{0.5}(BMO)_{0.5} atomic checkerboard structures composed of BFO and BMO perovskite unit cells [20]. The columnar structure (not a single phase structure) has alternating BFO (AF coupled) and BMO (FM coupled) pillars, and was only marginally in higher energy than the AF coupled ground state. In principle, such ordering would generate a mean moment of approximately 2μ_{B} per unit cell. Even in systems such as the double perovskite Sr₂FeMnO₆ in which the ordered state has the lowest energy, ordering is inevitably imperfect, and so the actually magnetic moment is less than that theoretically predicted [22].

In common with Bi et al. [23], no evidence was found that supports an ordered double perovskite Bi₂FeMnO₆ (which even if ferrimagnetically-ordered would yield an average moment of only approximately 0.5μ_{B} per unit cell) but from the magnetization values recorded it is likely that some ordering of Fe and Mn occurs in the structure, but this is very hard to measure.

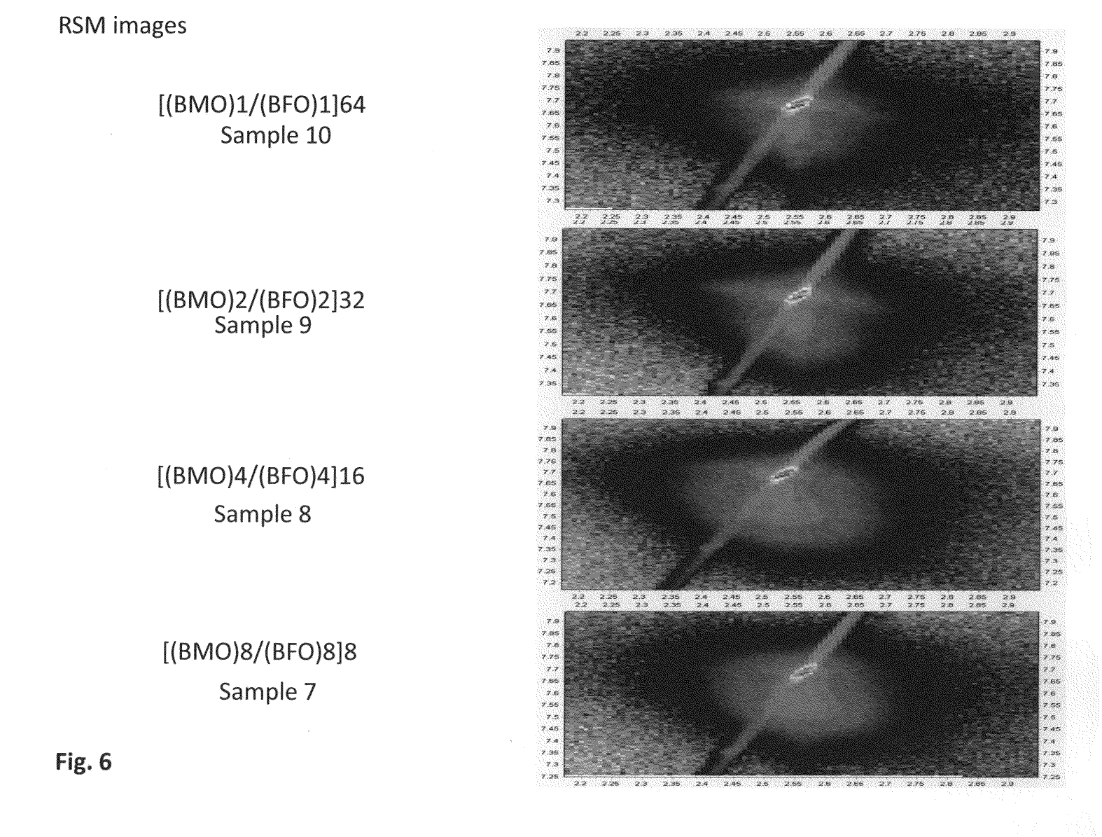

Alternating BFO and BMO multilayered films were prepared. Both layer thicknesses were equivalent for the 2 different materials. The individual layers had thicknesses in the range of 1-8 (0.38 nm-1.52 nm) unit cell thickness. FIG. 6 shows x-ray reciprocal space maps of the substrate STO peak (centre is red) and the BFO/BMO peak. We see that for 1 and 2 unit cells multilayered samples (10 and 9), the BFO/BMO peak is highly strained since it is sharp and close to the STO peak. For the 4 and 8 unit cell samples, however, the peak is considerably broadened and further away from the STO peak, indicating relaxation of the structure. The relaxed structures have weaker room temperature magnetism indicating the need to have a highly strained material.

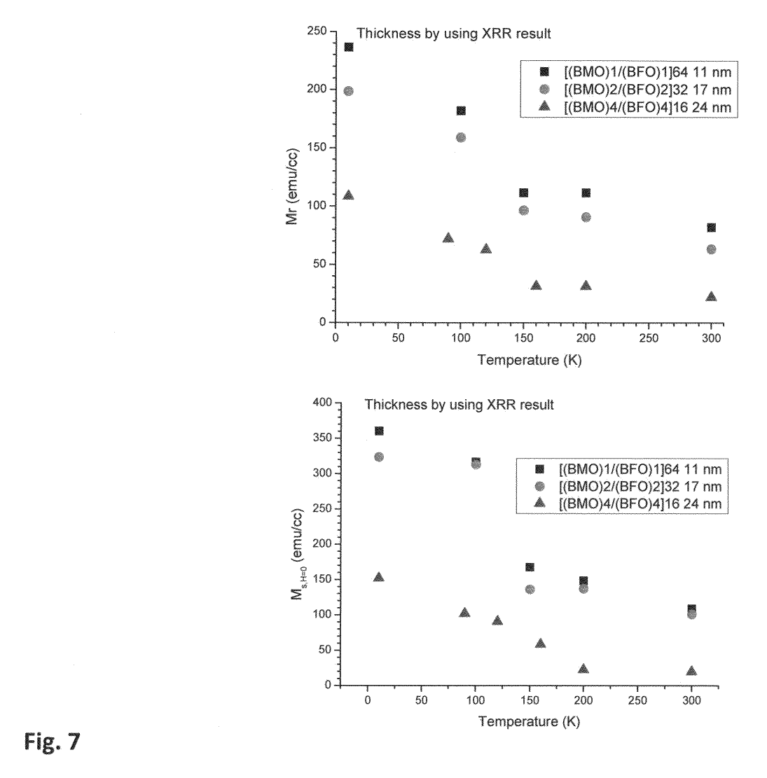

FIG. 7 shows remnant magnetization (Mᵣ) versus temperature (top panel) and saturation magnetization (Mₛ) versus temperature (bottom panel) for the multilayered films for 1, 2 and 4 unit cells. Ms (H=0) was obtained by linear extrapolation from high field (5 Tesla). The strong room temperature (300 K) magnetization values are apparent for the 1 and 2 unit cell (most highly strained) films with values of approximately 80 emu/cc for Mᵣ and approximately 100 emu/cc (M_{S}).

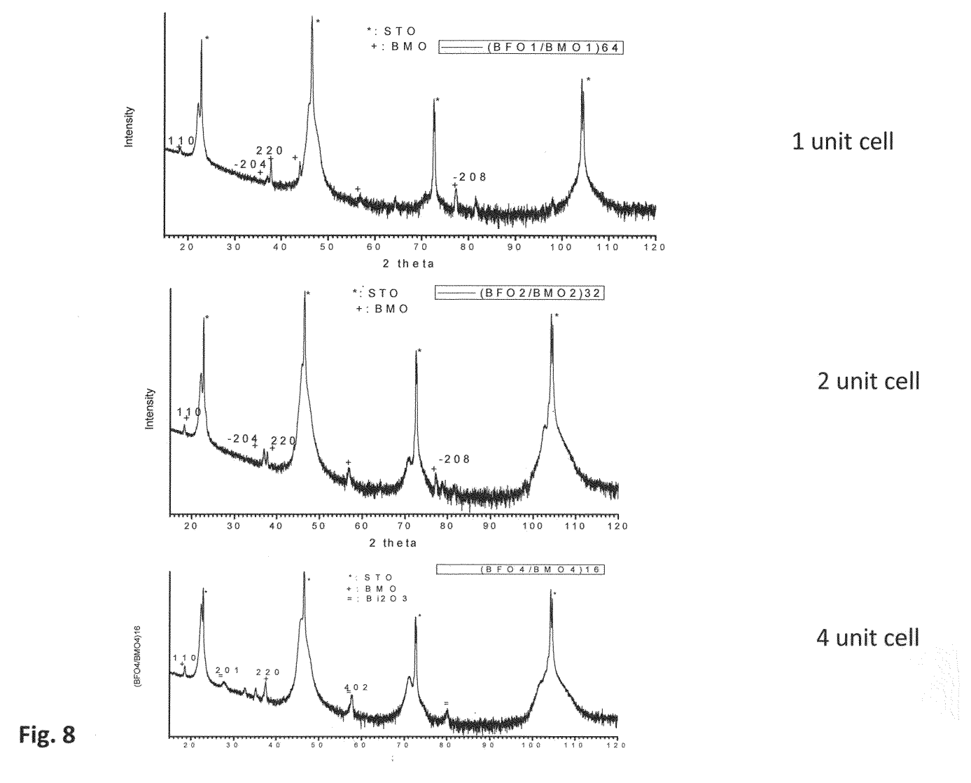

FIG. 8 compares the x-ray diffraction traces for the 1, 2, and 4 unit cell samples.

An impurity phase (Bi₂O₃) appears for the 4 until cell sample. For the 8 unit cell sample (not shown) the amount of impurities is even greater. Both the 4 and 8 unit cell samples have relaxed lattice constants and weak magnetic properties. The remnant magnetization values for the optimum BFMO or multilayered BFO/BMO films at 300 K were also high (i.e. up to 80 emu/cc, see FIGS. 3 and 7) which is very promising for room temperature spin filter devices where no such room temperature ferromagnetic insulators exist currently.

In conclusion, magnetoferroic articles including substrates and high-quality, strained, epitaxial single phase BiFe_{0.5}Mn_{0.5}O₃ (BFMO) thin films and BFO/BMO multilayers with a high magnetic transition temperature of approximately 600 K and magnetic moment as high as 100 emu/cc at 300 K and 3 kOe were prepared. They showed ferroelectricity at room temperature. These strongly enhanced properties are observed only in highly strained, highly epitaxial tetragonal, single-phase films. Some Fe and Mn ordering appears to be important for achieving strong magnetism. These articles hold great promise for spin filter and magnetoelectric random access memory applications.

The foregoing description of the invention has been presented for purposes of illustration and description and is not intended to be exhaustive or to limit the invention to the precise form disclosed, and obviously many modifications and variations are possible in light of the above teaching. For example, while embodiment films were prepared by pulsed laser deposition, other deposition techniques could be used. For example, molecular beam epitaxy, and chemical vapor deposition could be used to prepare these films.

The embodiments were chosen and described in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

### REFERENCES

The following references are incorporated by reference herein.
[1] Gajek et al., “Tunnel Junctions with Multiferroic Barriers,” Nature Materials, March 2007, vol. 6, pp. 296-302.
[2] Santos et al., “Determining Exchange Spinning in a Magnetic Semiconductor by Spin-Filter Tunneling,” Phys. Rev. Lett., September 2008, vol. 101, pp. 147201-1 through 147201-4.
[3] Hill, “Why Are There so Few Magnetic Ferroelectrics?,” J. Phys. Chemistry B, 2000, vol. 104, pp. 6694-6709.
[4] Ramesh et al., “Multiferroics: Progress and Prospects in Thin Films,” Nature Materials, January 2007, vol. 1, pp. 21-29.
[5] Manoj et al., “Spin-glass transition in single-crystal BiFeO₃,” Phys. Rev. B, April 2008, vol. 77, pp. 144403-1 through 144403-5.
[6] Spaldin et al., “The Renaissance of Magnetoelectric Multiferroics,” Science, July 2005, vol. 309, pp. 391-392.
[7] Moreira dos Santos et al., “Evidence for the Likely Occurrence of Magnetoferroelectricity in the Simple Perovskite, BiMnO₃,” Solid State Commun., April 2002, vol. 122, pp. 49-52.
[8] Sugawara et al., “Magnetic Properties and Crystal Distortion of BiMnO₃ and BiCrO₃,” J. Phys. Soc. Japan, December 1968, vol. 25, pp. 1553-1558.
[9] Faqir et al., “High-Temperature XRD and DTA Studies of BiMnO₃ Perovskite,” J. Solid State Chem., January 1999, vol. 142, pp. 113-119.
[10] Moreira dos Santos et al., “Epitaxial growth and properties of metastable BiMnO₃ thin films,” Appl. Phys. Lett., January 2004, vol. 84, pp. 91-93.
[11] Teague et al., “Dielectric Hysteresis in Single Crystal BiFeO₃,” Solid State Communications, 1970, vol. 8, pp. 1073-1074.
[12] Bea et al., Appl. Phys. Lett., “Influence of parasitic phases on the properties of BiFeO3 epitaxial thin films,” August 2005, vol. 87, pp. 072508-1 through 072508-3.
[13] Ruette et al., “Magnetic-field-induced transition in BiFeO₃ observed by high-field electron spin resonance: Cycloidal to homogeneous spin order,” Phys. Rev. B, 2004, vol. 69, no. 6, pp. 064114-1 through 064114-7.
[14] Li et al., “Dramatically enhanced polarization in (001), (101), and (111) BiFeO₃ thin films due to epitaxial-induced transitions,” Appl. Phys. Lett., June 2004, vol. 84, pp. 5261-5263.
[15] Azuma et al., “Designed Ferromagnetic, Ferroelectric Bi₂NiMnO₆,” J. Am. Chem. Soc., June 2005, vol. 127, pp. 8889-8892.
[16] Yasui et al., “Analysis for crystal structure of Bi(Fe,Sc)O₃ thin films and their electrical properties,” Appl. Phys. Lett., June 2007, vol. 91, pp. 022906-1 through 022906-3.
[17] Rana et al., “Thickness dependence of the structure and magnetization of BeFeO₃ thin films on (LaAlO₃)_{0.3}(Sr₂AlTaO₆)_{0.7} (001) substrate,” Phys. Rev. B, February 2007, vol. 75, pp. 060405-1 through 060405-4.
[18] Azuma et al., “Magnetic and structural properties of BiFe₁₋ₓMnₓO₃,” Journal of Magnetism and Magnetic Materials, November 2006 (available online), vol. 310, pp. 1177-1179.
[19] Rana et al., “Implications of phase segregation on structure, terahertz emission and magnetization of Bi(Fe₁₋ₓMnₓ₎O₃ (0≦x≦0.5) thin films,” Europhysics Letters, December 2008, vol. 84, pp. 67016-p1 through 67016-p5.
[20] Pálová et al., “Magnetostructural Effect in the Multiferroic BiFeO₃—BiMnO₃ Checkerboard from First Principles,” Phys. Rev. Lett., January 2010, vol. 104, pp. 037202-1 through 037202-4.
[21] Selbach et al., “Structure and Properties of Multiferroic Oxygen Hyperstoichiometric BiFe₁₋ₓMnₓO_{3+δ},” Chem. Mater., October 2009, vol. 21, pp. 5176-5186.
[22] Venimadhav et al., “Ferromagnetic spin ordering in disordered Sr₂FeMoO₆ films,” Sol. St. Commun., March 2004, vol. 130, pp. 631-636.
[23] Bi et al., Phys. Rev. B, “Structural, magnetic, and optical properties of BiFeO₃ and Bi₂MnFeO₆ epitaxial films: An experimental and first-principles study,” September 2008, vol. 78, pp. 104106-1 through 104106-10.
[24] Dass et al., “Multiple magnetic phases of Ln₂CoMn_{6-δ} (0≦δ≦0.05),” Phys. Rev. B, January 2003, vol. 67, pp. 014401-1 through 014401-9.
[25] Jonker, “Magnetic and Semiconducting Properties of Perovskites Containing Manganese and Cobalt,” J. Appl. Phys., 1966, vol. 37, pp. 1424-1430.
[26] Gajek et al., Phys. Rev. B, “Spin filtering through ferromagnetic BiMnO₃ tunnel barriers,” July 2005, vol. 72, pp. 020406-1 through 020406-4.
[27] Benz et al., “Anisotropy parameters and coercivity for sintered Co5Sm permanent magnet alloys,” J. Appl. Phys., November 1972, vol. 43, pp. 4733-4736.

What is claimed is:

1. A magnetic and ferroelectric article comprising:
a strained, single phase, epitaxial thin film portion comprising a composition of the formula BiFe_{0.5}Mn_{0.5}O₃, and
a substrate portion for supporting said thin film portion, said substrate portion providing sufficient strain to said thin film to provide said article with both ferromagnetic and ferroelectric properties at and above room temperature.

2. The article of claim 1, wherein said substrate comprises strontium titanate and Nb-doped strontium titanate.

3. The article of claim 1, wherein said substrate is selected from LaAlO₃, MgO, NdGaO₃, MgAl₂O₄, ZrO₂, YSZ, (La,Sr)(Al,Ta)O₃.

4. A process for preparing a magnetic and ferroelectric article, comprising:
forming a mixture of bismuth oxide, iron oxide, and manganese oxide to provide a Bi to Fe to Mn ratio of 1:0.5:0.5,
sintering the mixture to form a target for deposition onto a substrate, and
using the target under conditions suitable to deposit a strained, single phase epitaxial film of a composition of the formula BiFe_{0.5}Mn_{0.5}O₃ onto a substrate chosen to provide the epitaxial film with sufficient strain to provide a magnetoferroic article with both ferromagnetic and ferroelectric properties at and above room temperature.

5. The process of claim 4, wherein the substrate comprises strontium titanate and Nb-doped strontium titanate.

6. The process of claim 4, wherein the substrate is selected from LaAlO₃, MgO, NdGaO₃, MgAl₂O₄, ZrO₂, YSZ, (La,Sr)(Al,Ta)O₃.

7. The process of claim 4, wherein the oxides in the starting mixture are each at least 99.99% pure.

8. The process of claim 4, wherein the step of using the target to deposit a strained, single phase epitaxial film comprises a deposition technique selected from pulsed laser deposition, sputtering, co-evaporation, molecular beam epitaxy, and chemical vapor deposition.

9. The process of claim 4, wherein the step of using the target to deposit a strained, single phase epitaxial film comprises pulsed laser deposition.

10. The process of claim 4, wherein the step of using the target to deposit a strained, single phase epitaxial film comprises a deposition temperature in a range 600° C. and 900° C.

11. The process of claim 4, wherein the step of using the target to deposit a strained, single phase epitaxial film comprises a pulse rate from about 1 Hz to about 10.

12. The process of claim 4, wherein the step of using the target to deposit a strained, single phase epitaxial film comprises a deposition temperature from about 650° C. to about 850° C.

13. The process of claim 4, wherein the range of substrates temperatures used during the film growth is 600° C.-900° C., the preferred temperature being around 820° C.

14. The process of claim 4, wherein the oxygen pressure used during the film growth is 10 millitorr to 350 millitorr.

15. The process of claim 4, wherein the oxygen pressure used during film growth is from about 200 millitorr.

16. The process of claim 5, wherein the growth rate used during the film growth is in a range of about 0.01-0.1 nm/min.

17. The process of claim 5, wherein the growth rate use during the film grow is about 0.2 nm/min.

18. A strained magnetic multilayered article comprising:
a substrate for supporting an alternating multilayered structure; and
a multilayered structure comprising alternating layers of BiMnO₃ layers and BiFeO₃, each of said layers comprising a thickness of from 0.38 nm to 1.52 nm.

19. The strained multilayered article of claim 18, wherein said multilayered structure comprises sufficient strain to render the article ferroelectric room temperature.
